(19) United States
(12) Patent Application Publication
(10) Pub. No.: US 2017/0037516 A1
(43) Pub. Date: Feb. 9, 2017

(54) ELECTRODE CONTAMINATION-PROOF DEVICE AND FILM COATING SYSTEM

(71) Applicant: INDUSTRIAL TECHNOLOGY RESEARCH INSTITUTE, Hsin-chu (TW)

(72) Inventors: JUI-MEI HSU, Zhubei City (TW); CHEN-DER TSAI, Hsinchu County (TW); CHIH-CHIANG WENG, Zhongli City (TW)

(21) Appl. No.: 14/965,106

(22) Filed: Dec. 10, 2015

(30) Foreign Application Priority Data
Aug. 6, 2015 (TW) 104125685

(51) Int. Cl. C23C 16/50

(52) U.S. Cl. CPC C23C 16/50

(57) ABSTRACT

An electrode contamination-proof device includes a first electrode structure, a second electrode structure, a sacrificing layer, and scroll driving devices. The second electrode structure and the first electrode structure are oppositely disposed. The sacrificing layer being positioned between the first electrode structure and the second electrode structure is capable of movably and tightly clinging on the exterior surface of the first electrode structure. The scroll driving devices is capable of driving the sacrificing layer to scroll around the scroll driving device. Besides, a film coating system is also provided.

### CROSS-REFERENCE TO RELATED APPLICATIONS

This application also claims priority to Taiwan Patent Application No. 104125685 filed in the Taiwan Patent Office on Aug. 6, 2015, the entire content of which is incorporated herein by reference.

### TECHNICAL FIELD

The disclosure relates to an electrode contamination-proof device and film coating system, and more particularly, to an electrode contamination-proof device and film coating system used for atmospheric pressure plasma.

### BACKGROUND

There are highly active species such as electrons, ions, free radicals, and ultra violet (UV) in the plasma. The vacuum plasma technology, including etching and deposition, is widely used in high value-added semiconductor and optoelectronics manufacturing process. Nevertheless, since the vacuum plasma requires expensive vacuum chamber and vacuuming facility, comparing with the vacuum plasma technology, the atmospheric pressure plasma is capable of substantially reducing the furnishing cost.

In the plasma film coating process, since the atmospheric pressure plasma can be generated under one atmospheric pressure, there is no need to have expensive vacuum chamber and vacuuming facility. In addition, since the atmospheric plasma has the advantages of not being subjected to the limitation of the dimension of the chamber, apt to extend, and easily be wielded in the continuous process, the range of the application of the atmospheric plasma can be greatly enlarged. For instance, besides being used for surface treatment of a substrate including cleaning, activation, and etching etc., it can also be applied for thin film deposition.

In a linear atmospheric plasma facility, after the plasma is generated by applying high electric voltage between the two electrodes, film is deposited on a substrate. However, as far as the way of deposition of the currently used process, the electrodes are apt to be contaminated by the film deposition process, thereby difficulties exist, in a long-time film coating application.

### SUMMARY

An embodiment of the disclosure provides an electrode contamination-proof device that includes a first electrode structure, a second electrode structure, a sacrificing layer, and a scroll driving device. The second electrode structure and the first electrode structure are oppositely disposed, and the first electrode structure and the second electrode structure (30) are apart with a space. The sacrificing layer being positioned between the first electrode structure and the second electrode structure is capable of movably and tightly clinging on the exterior surface of the first electrode structure and is used for isolating a portion of the first electrode structure. The scroll driving device drives the sacrificing layer and to scroll the sacrificing layer (120) on the scroll driving devices,

Another embodiment of the disclosure provides a film coating system which include a first electrode structure; a second electrode structure oppositely disposing and having a space with respect to the first electrode structure; a substrate furnished in the second electrode structure is positioned between the first electrode structure and the second electrode structure; a sacrificing layer being positioned between the first electrode structure and the second electrode structure, is capable of moving and tightly clinging on the exterior surface for isolating from the first electrode structure; and a scroll driving device driving the sacrificing layer to move from first rolling element to the second rolling element and tightly cling to the exterior surface of the first electrode structure.

Further embodiment of the disclosure provides a film coating system which includes a first electrode structure; a second electrode structure oppositely disposing and having a space with respect to the first electrode structure; a substrate to be deposited being positioned between the first electrode structure and the second electrode structure is used for isolating the second electrode structure; a sacrificing layer being positioned between the first electrode structure and the second electrode structure, is capable of moving and tightly clinging on the exterior surface for isolating from the first electrode structure; and a scroll driving device driving the sacrificing layer to move from first rolling element to the second rolling element and tightly cling to the exterior surface of the first electrode structure.

Based on the above-mentioned explanation, the electrode contamination-proof device and the film coating system of the disclosure, the sacrificing layer is tightly clung on the exterior surface of an electrode structure, and as the plasma is generated in the plasma generated area between the sacrificing layer and its corresponding electrode structure, since the first electrode structure is isolated by the sacrificing layer making the sediment after the film coating process does not directly contact with the electrode structures, the contamination of the electrode structures can be avoided.

### BRIEF DESCRIPTION OF THE DRAWINGS

FIG. 1 is a schematic drawing of an embodiment of the film coating system of the disclosure;

FIG. 2 is a schematic drawing of another embodiment of the film coating system of the disclosure;

FIG. 3 is a schematic drawing of a more embodiment of the film coating system of the disclosure;

FIG. 4 is a schematic drawing of a further more embodiment of the film coating system of the disclosure;

FIG. 5 is a schematic drawing of again further embodiment of the film coating system of the disclosure;

FIG. 6 is a pictorial view of an embodiment of the electrode contamination-proof device of the disclosure;

FIG. 7 is an exploded view of the electrode contamination-proof device of FIG. 6 of the disclosure;

FIG. 8 is an exploded view of the precursor gas-import device of FIG. 7 of the disclosure.

### DETAILED DESCRIPTION OF THE PREFERRED EMBODIMENT

The accomplishment of this and other objects of the disclosure will become apparent from the following description and its accompanying drawings, but it can not limit the protection range of the disclosure.

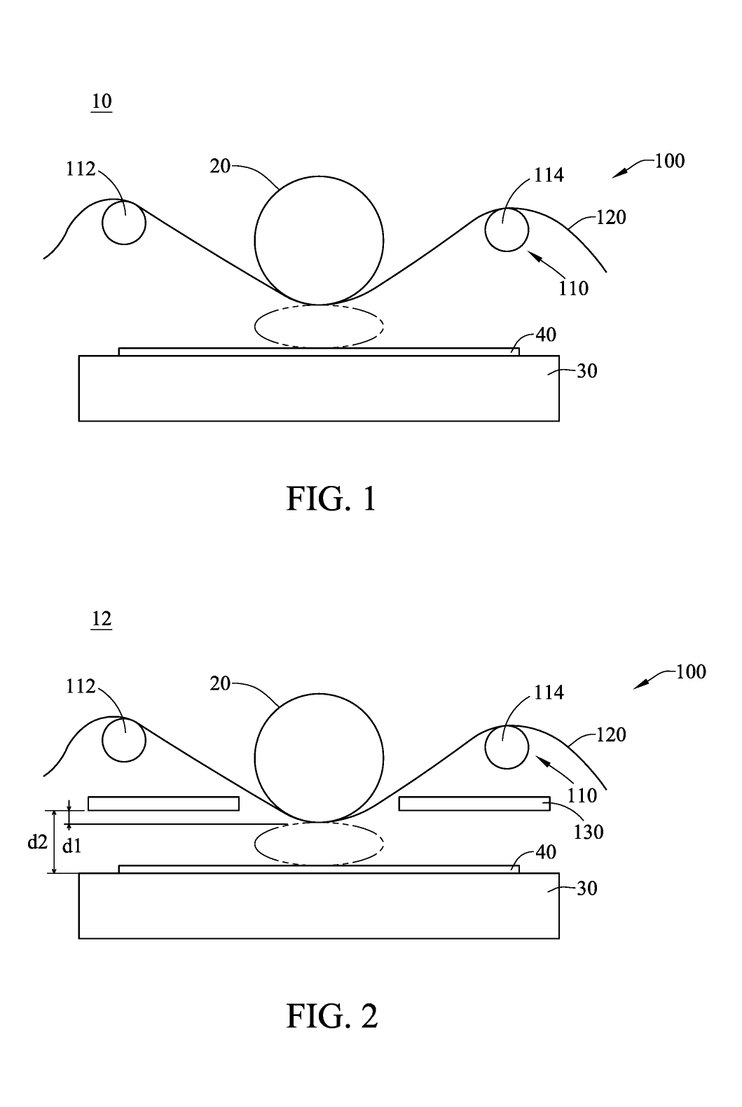

FIG. 1 is a schematic drawing of an embodiment of the film coating system of the disclosure. As shown in FIG. 1, in the embodiment of the disclosure, the film coating system (10) includes a first electrode structure (20), a second electrode structure (30), a substrate (40), two scroll driving devices (110) and a sacrificing layer (120) wherein the film coating system (10) employs, for example, a plasma film coating processing substrate (40) while the electrode contamination-proof device (100) of the film coating system (10) includes the first electrode structure (20), the second electrode structure (30), the scroll driving devices (110) and the sacrificing layer (120). Moreover, the substrate (40) being furnished on the second electrode structure (30) is positioned between the first electrode structure (20) and the second electrode structure (30).

The first electrode structure (20), for example, is a metal electrode but is not limited to a metal electrode in this embodiment. In the other embodiments, the first electrode structure (20), for example, includes a dielectric which is, for example, a quartz or a ceramics. In other words, the first electrode structure (20) can be an electrode isolated by dielectric material employed by quartz or ceramics depending on the actual process.

The first electrode structure (20) being relatively disposed with the second electrode structure (30) is apart by a distance with the second electrode structure (30). Moreover, the first electrode structure (20) and the second electrode structure (30) are corresponding electrodes each other, in other words, the first electrode structure (20) can be connected to, for instance, the ground while the second electrode structure (30) can be acted as high voltage pole. What is more, in the other embodiment, the first electrode structure (20) can be acted as high voltage pole while the second electrode structure (30) can be connected to ground.

The substrate (40) having thickness, for example, 0.1 mm through 2 mm and being furnished on the second electrode structure (30) is positioned between the first electrode structure (20) and the second electrode structure (30). The substrate (40) is made of, for example, hard material or soft material (e.g. flexible soft material). The choice of the material of the substrate (40) depends on the actual manufacturing process and is not limited with respect to it.

The sacrificing layer (120) is positioned between the first electrode structure (20) and the second electrode structure (30). The scroll driving devices (110) includes a first rolling element (112) and a second rolling element (114) that are positioned on both sides of the first electrode structure (20) respectively. The sacrificing layer (120) is connected from the first rolling element (112) to the second rolling element (114). In the present embodiment, the first electrode structure (20) is a cylindrical electrode. The sacrificing layer (120) is driven by the first rolling element (112) and is clung on the second rolling element (114). Moreover, the sacrificing layer (120) being capable of movably clinging on the exterior surface of the second rolling element (114) is capable of isolating the first electrode structure (20) under this disposition.

The sacrificing layer (120) having its dielectric constant between 2 and 10 and its thickness, for example, between 30 through 300 μm, is, for example, a dielectric film. In a further embodiment, the material of the sacrificing layer (120), including a heat-resistant material having high-temperature-resistant characteristic, includes Polyimide (PI), Polyethylene terephthalate (PET), Polymethylmethacrylate (PMMA, Acryl plastic) or glass. The glass transition temperature (Tg) of the sacrificing layer (120), for example, is greater than 80° C.

Under this disposition, the plasma (shown in dotted line as shown in FIG. 1) is generated in the plasma generated area between the sacrificing layer (120) and its corresponding electrodes, i.e. the first electrode structure (20) and the second electrode structure (30). Since the first electrode structure (20) is isolated by the sacrificing layer (120) the sediment after the film coating process will not directly contact the first electrode structure (20), thereby, the first electrode structure (20) is capable of avoiding to be contaminated.

What is more, the adhered sediment on a portion of the sacrificing layer (120) is capable of being transferred by a scroll driving devices (110) to the other scroll driving devices (110) so as to replace a new sacrificing layer (120). Furthermore, the present embodiment is capable of monitoring the rotating speed of the scroll driving devices (110) in accordance with the depositing condition of the coating film and the depositing speed of various reactive substances to further adjust the moving speed of the sacrificing layer (120) to ensure the maintenance of purity of the first electrode structure (20) after a long-term film coating process without affecting the film forming condition and to be able to improve the film coating quality.

In addition, since the sacrificing layer (120) is tightly clung on the exterior surface of the first electrode structure (20) without any clearance, the gas flow of the reactive gas is capable of flowing along the sacrificing layer (120) toward the plasma generated area (the area shown in dotted line as shown in FIG. 1). In other words, the sacrificing layer (120) can not only prevent the reactive gas from directly contacting with the first electrode structure (20) but also isolate the reactive gas to flow toward the other area causing deposition.

FIG. 2 is a schematic drawing of another embodiment of the film coating system of the disclosure. As shown in FIG. 2, what is needed to explain is that the film coating system (12) shown in FIG. 2 is similar to the film coating system (10) in FIG. 1 where the same elements are denoted by the same label and are having the same efficacies, thereby, it is not necessary to repeat here. The difference between them is explained as follows:

What is the difference between FIG. 2 and FIG. 1 is that the electrode contamination-proof device (100) of the film coating system (12) includes a precursor gas-import device (130).

The precursor gas-import device (130) is positioned adjacent to the first electrode structure (20) and the sacrificing layer (120), in other words, a set of precursor gas-import devices (130) is furnished within the plasma generated area in the film coating system (10) for providing uniform gas flow.

In the present embodiment, the portion of the first electrode structure (20) that is contacted with the sacrificing layer (120) is protruded out of the precursor gas-import device (130), in other words, the sacrificing layer (120) and an end of the first electrode structure (20) isolated by the sacrificing layer (120) is to be at a distance of d1, this distance d1 is, for example, 2 mm from the precursor gas-import device (130). The precursor gas-import device (130) is to be at a distance of d2, this distance d2 is, for example, less than 6 mm from the second electrode structure (30) to form positive pressure and to reduce the outer gas flow entering the plasma generated area.

Furthermore, there are two precursor gas-import devices (130) that are furnished on each side of the plasma generated area. Therefore, the horizontal distance between the precursor gas-import device (130) and the plasma generated area can be adjusted. In this way, the gas inlet distance can be adjusted according to the deposition condition of the film coating process and the deposition speed of various reactive substances. Besides, the accumulation of the deposition material of the film coating process that blocks the gas flow of the reactive substance can be avoided.

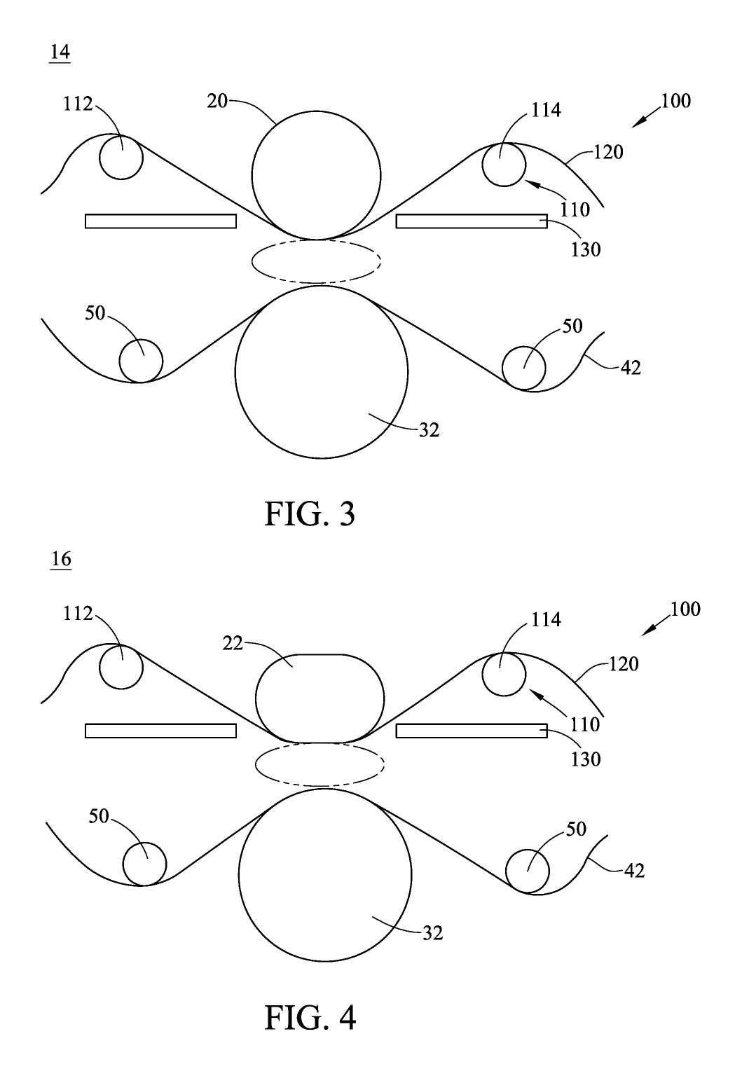

In the embodiment of FIG. 1 and FIG. 2, the first electrode structures (20) are in cylindrical shape while the second electrode structures (30) are either a rectangular or flat-plate type platform making the corresponding electrodes be all in cylindrical corresponding to rectangular (or plan) shapes. However, the shapes of the electrodes are not limited to the present embodiment. Followings are illustrated examples by FIG. 3 through FIG. 5.

FIG. 4 is a schematic drawing of a further more embodiment of the film coating system of the disclosure. As shown in FIG. 4, what is needed to explain is that the film coating system (16) shown in FIG. 4 is similar to the film coating system (14) in FIG. 3 where the same elements are denoted by the same label and are having the same efficacies, thereby, it is not necessary to repeat here. The difference between them is explained as follows:

What is the difference between FIG. 3 and FIG. 2 is that the second electrode structure (32) is an cylindrical electrode, i.e. the corresponding electrode shapes of the present embodiment is cylindrical to cylindrical while a substrate (42) is made of flexible material. The cylindrical second electrode structure (32) is isolated by the flexible substrate (42). What is the difference between the substrate (42) in FIG. 3 and the substrate (40) in FIG. 2 & FIG. 1 lies in the fact that the flexible substrate (42) is a continuous long strip in shape while the substrate (40) is a plate in shape. In other words, the selection of the made-of material of the substrate (40) of the disclosure can be either a rigid material or a flexible material depending on the actual manufacturing process.

The film coating system (14) further includes two driving devices (50) where one of two driving devices (50) can be used for driving the flexible substrate (42) to move, and to have the flexible substrate material (42) scroll toward the other driving device (50).

FIG. 4 is a schematic drawing of a further more embodiment of the film coating system of the disclosure. As shown in FIG. 4, what is needed to explain is that the film coating system (16) shown in FIG. 4 is similar to the film coating system (14) in FIG. 3 where the same elements are denoted by the same label and are having the same efficacies, thereby, it is not necessary to repeat here. The difference between them is explained as follows:

What is the difference between FIG. 4 and FIG. 3 lies in that the first electrode structure (22) is an elliptical electrode, i.e. the corresponding electrode shapes (the first electrode structure (20) and the second electrode structure (30)) of the present embodiment is elliptical to cylindrical. In an embodiment not shown in the Fig., the corresponding electrode shapes, such as elliptical shape to rectangular shape or elliptical shape to elliptical shape. What is needed to explain is that although the first electrode structure (22) appears in elliptical shape, since the sacrificing layer (120) is still tightly clung on the exterior surface of the first electrode structure (22) without any clearance, the resulting deposition due to the flowing-in of the reactive gas can be avoided.

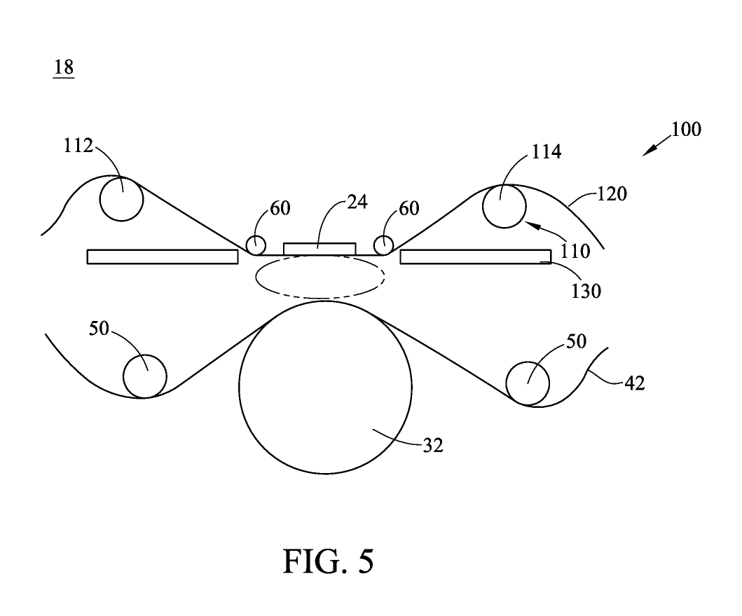

FIG. 5 is a schematic drawing of again further embodiment of the film coating system of the disclosure. As shown in FIG. 5, what is needed to explain is that the film coating system (18) shown in FIG. 5 is similar to the film coating system (16) in FIG. 4 where the same elements are denoted by the same label and are having the same efficacies, thereby, it is not necessary to repeat here. The difference between them is explained as follows:

What is the difference between FIG. 5 and FIG. 4 is that the first electrode structure (24) is a rectangular electrode or flat-plate type electrode, in other words, in an embodiment not shown in the Fig., the corresponding electrode shapes, such as rectangular shape to rectangular shape or rectangular shape to elliptical shape.

The film coating system (18) further includes two secured elements (60). The first electrode structure (24) and the two secured elements (60) are tightly clung by the sacrificing layer (120) respectively, where the two secured elements (60) being in cylindrical shape are positioned on both sides of the first electrode structure (24). Under this disposition, the sacrificing layer (120) will not be damaged by both sides of the first electrode structure (24), and the exterior surface of the first electrode structure (24) is capable of being tightly clung by the sacrificing layer (120) since the sacrificing layer (120) on both sides of the first electrode structure (24) is repressed by the two secured elements (60).

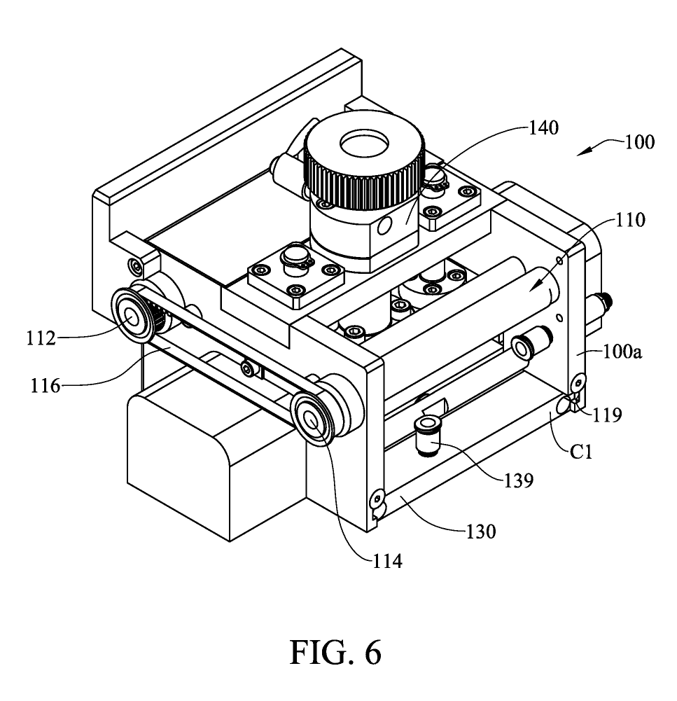

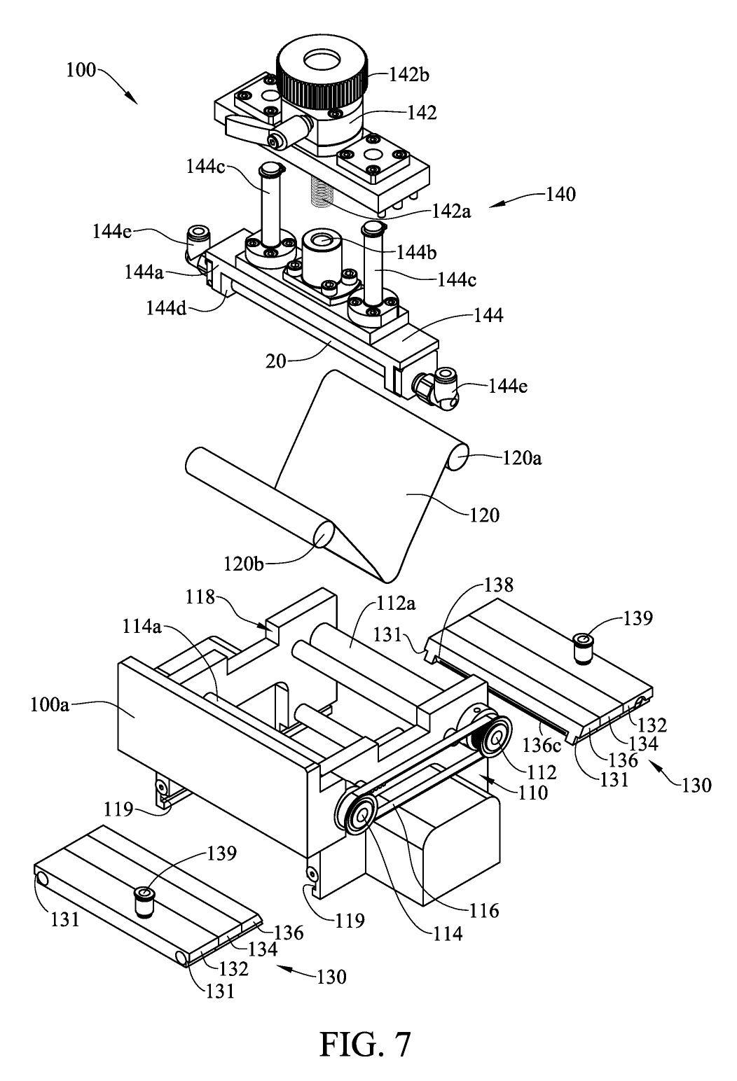

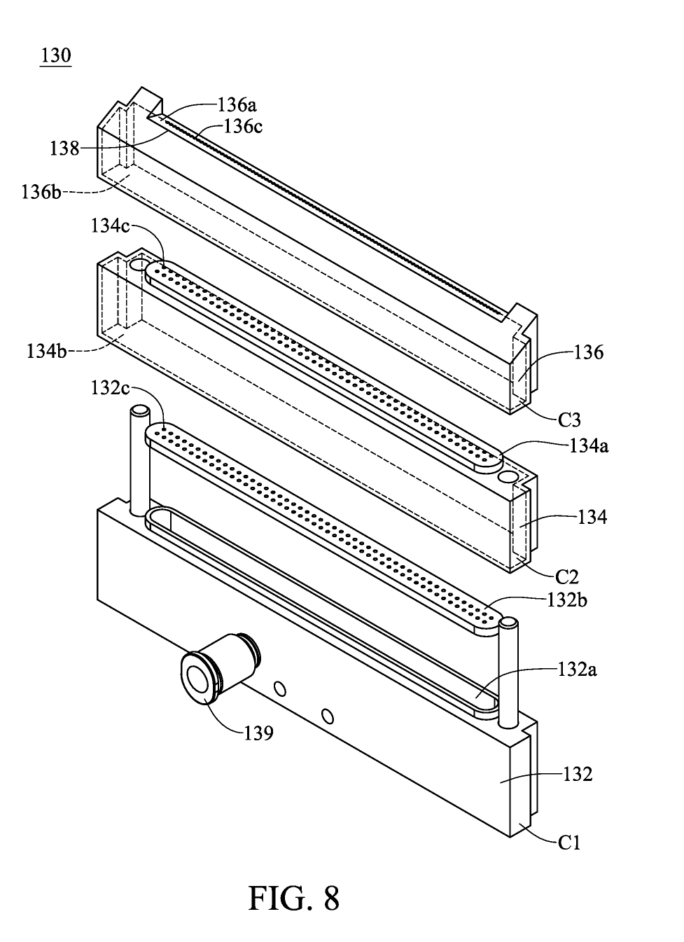

FIG. 6 is a pictorial view of an embodiment of the electrode contamination-proof device of the disclosure, and FIG. 7 is an exploded view of the electrode contamination-proof device of FIG. 6 of the disclosure, while FIG. 8 is an exploded view of the precursor gas-import device of FIG. 7 of the disclosure. As shown in FIG. 6, FIG.7, and FIG. 8, and also referring to FIG. 2, what is needed to explain is that the electrode contamination-proof device (100) as shown in FIG. 6 through FIG. 8 is an embodiment actually done by referring to the film coating system (10) of FIG. 2. Therefore, the electrode contamination-proof device (100) shown in FIG. 6 through FIG. 8 is similar to the electrode contamination-proof device (100) shown in FIG. 2 where the same elements are denoted by the same label and are having the same efficacies, thereby, it is not necessary to repeat here. The difference between them is explained as follows:

In the present embodiment, the electrode contamination-proof device (100) further includes a elevating mechanism (140) and a supporting frame (100a). The first electrode structure (20), the scroll driving devices (110), the sacrificing layer (120) and the precursor gas-import device (130) are furnished respectively at the supporting frame (100a).

The elevating mechanism (140) is connected to the supporting frame (100a) while the first electrode structure (20) is connected to the elevating mechanism (140) which is used for adjusting the space, as shown in FIG. 2, between the first electrode structure (20) and the second electrode structure (30). The space between the corresponding electrodes, i.e. between the first electrode structure (20) and the second electrode structure (30) is, for example, between 0.5 mm through 4 mm.

The elevating mechanism (140) includes a top seat (142) and a connecting seat (144). The top seat (142) connected to the connecting seat (144).

The top seat (142) includes a screw rod (142a) and a rotating member (142b). The rotating member (142b) is connected to the screw rod (142a).

The connecting seat (144) includes a main body (144a), a screw hole (144b), two guided rods (144c), and two cooling water-pipe joints (144e).

The screw hole (144b) and the two guided rods (144c) are all positioned on the main body (144a) and the two guided rods (144c) are positioned on both sides of the screw hole (144b) respectively.

To illustrate in detail, a recess portion (144d) is furnished below the main body (144a) for providing the room for the first electrode structure (20). The cooling water-pipe joints (144e) being positioned at both ends of the main body (144a) and connected to the first electrode structure (20) is for cooling the first electrode structure (20).

The screw rod (142a) is connected to the screw hole (144b) of the connecting seat (144) to make the top seat (142) combine with the connecting seat (144). Since the first electrode structure (20) is furnished at the recess portion (144d) below the connecting seat (144), as the connecting seat (144) is placed in an indent (118) of the supporting frame (100a) to have the elevating mechanism (140) install to the supporting frame (100a). In this way, by rotating the rotating member (142b) it is capable to make the connecting seat (144) move to let the first electrode structure (20) adjust its position.

The scroll driving devices (110) includes the first rolling element (112), the second rolling element (114), and a transmission element (116).

The first rolling element (112) and the second rolling element (114) are furnished the opposite ends of the supporting frame (100a) while the transmission element (116) is connected between the first rolling element (112) and the second rolling element (114) making the first rolling element (112) and the second rolling element (114) having the same rolling speed.

The first rolling element (112) having a roller (112a) and the second rolling element (114) having a roller (114a) are rotating through the transmission by the transmission element (116).

The sacrificing layer (120) having a first end (120a) fitting on the roller (112a) of the first rolling element (112) and a second end (120b) fitting on the roller (114a) of the second rolling element (114).

As shown in FIG. 7, the precursor gas-import device (130) has a bump (131) furnished at both ends thereof. The supporting frame (100a) having a containing space providing there-below and a sliding channel (119) furnished on each inner side of the wall of the containing space corresponding to the bumps (131) of the precursor gas-import device (130) provides the precursor gas-import device (130) with a space to have the bump (131) of the precursor gas-import device (130) engage with the sliding channel (119) making the precursor gas-import device (130) slide in the containing space of the supporting frame (100a). In addition, the precursor gas-import device (130) is capable of horizontally adjusting its position within the supporting frame (100a) through a screw rod unit.

The precursor gas-import device (130) includes a gas diffuser (132), a gas rectifier (134), a gas spurt (136), and an inlet part (139). The gas rectifier (134) being positioned between the gas diffuser (132) and the gas spurt (136) is communicative to both the gas diffuser (132) and the gas spurt (136) and the gas spurt (136) faces the first electrode structure (20).

What is more, as shown in FIG. 8, the gas rectifier (134) is plugged in the gas diffuser (132), and consequently the gas spurt (136) is plugged in the gas rectifier (134), thereby, the precursor gas-import device (130) is formed. The bumps C1, C2, C3 on both ends of the gas diffuser (132), gas rectifier (134), and gas spurt (136) respectively form the bump (131) of the precursor gas-import device (130).

The inlet part (139) for providing the place for gas flow is communicative to the precursor gas-import device (130).

The gas diffuser (132) includes a first ventilating part (132a), a diffusing part (132b), and a plurality of first throttling holes (132c).

The first ventilating part (132a) is a hollow body. The diffusing part (132b) is furnished at the first ventilating part (132a) while the first throttling holes (132c) is furnished at the diffusing part (132b). The first ventilating part (132a) is communicative to the diffusing part (132b) and the plurality of first throttling holes (132c).

The gas rectifier (134) includes a rectifying part (134a), a second ventilating part (134b), and a plurality of second throttling holes (134c).

The second ventilating part (134b) being a hollow body is communicative to the plurality of first throttling holes (132c). The rectifying part (134a) is furnished at the second ventilating part (134b) while the plurality of second throttling holes (134c) is furnished at the rectifying part (134a). The second ventilating part (134b) is communicative to the rectifying part (134a) and the plurality of second throttling holes (134c).

The gas spurt (136) includes a spur part (136a), a third ventilating part (136b), and a plurality of third throttling holes (136c). The third ventilating part (136b) being a hollow body is communicative to the plurality of second throttling holes (134c) and the third throttling holes (136c). In addition, a stop part (138) being appeared in slant surface is furnished at the front end of the gas spurt (136) which is also appeared in slant surface. What is more, the spur part (136a) is recessed at the stop part (138), i.e. the stop part (138) is protruded beyond the spur part (136a).

Under this disposition, the rotating member (142b) in the present embodiment is connected to the screw rod (142a) which in turn, is combined with the screw hole (144b). By rotating the rotating member (142b), the space between the first electrode structure (20), which is furnished below the connecting seat (144), and the second electrode structure (30) is adjusted. Consequently, by the use of the first rolling element (112), the tensile force of the sacrificing layer (120) is capable of being adjusted to assure that the sacrificing layer (120) is tightly pressed against the exterior surface of the first electrode structure (20).

As the scroll driving devices (110) drives the sacrificing layer (120), the sacrificing layer (120) moves from first rolling element (112) to second rolling element (114) and tightly clings to the exterior surface of the first electrode structure (20) while the second electrode structure (30) receives the necessarily-to-be changed sacrificing layer (120) transported from the first rolling element (112).

Besides, in the present embodiment, in addition to the fact that the rotating speed of both the first rolling element (112) and the second rolling element (114) can be adjusted in accordance with the deposition conditions of the film coating process and the deposition speed of various reactive substances, an appropriate adjustment to the sacrificing layer (120) can also be performed making the gas flow of the reactive gas capable of flowing to the plasma generated area (the area shown in dotted line as shown in FIG. 2) instead of flowing to the other areas.

Moreover, as the gas flow of the reactive gas flows through the precursor gas-import device (130), it first enter the gas diffuser (132) via the inlet part (139), then the gas-flow flows into the internal space of the first ventilating part (132a) and distributes the gas-flow to flow to the gas rectifier (134) through the first throttling holes (132c). Consequently, the gas-flow again flows into the internal space of the second ventilating part (134a) to reach once-more rectifying and distributes the gas-flow to flow to the gas spurt (136) through the second throttling holes (134c) of the rectifying part (134a). Consequently, the gas-flow flows into the internal space of the third ventilating part (136b) making the gas-flow uniformly mix, then spurs to the plasma generated area through the third throttling holes (136c). What is more, since the flow direction of the gas-flow of the reactive gas is blocked and limited by the stop part (138), it can be assured that the gas-flow, which is uniformly rectified through the precursor gas-import device (130), is capable of staying in the plasma generated area.

In addition, the precursor gas-import device (130) can further horizontally adjust the space to the plasma generated area by the use of screw rod unit. In this way, in addition to the fact that the gas importation distance can be adjusted in accordance with the deposition conditions of the film coating process and the deposition speed of various reactive substances by the use of the precursor gas-import device (130), the blocking of the deposition substance that affects the flow of the gas-flow of the reacting gas can also be avoided by adjusting the position of the precursor gas-import device (130).

To summarize the above-mentioned description, in the electrode contamination-proof device (100) and the film coating system (10) of the disclosure, to have the sacrificing layer (120) tightly cling on the exterior surface of the electrode structures, as the plasma is generated in the plasma generated area between the sacrificing layer (120) and its corresponding electrode structures, since the first electrode structure (20) is isolated by the sacrificing layer (120) making the deposition substance do not directly contact with the electrode structures, rather, adhere to the sacrificing layer (120) after the film coating process is performed, thereby, the electrode structures can avoid being contaminated.

Moreover, the disclosure is capable of moving away the sacrificing layer (120) by the use of the scroll driving devices (110) to change a new sacrificing layer (120), therefore, there is no need to spend time, manpower, and cost to clean the sacrificing layer (120) to save time on the process maintenance and cleaning. Furthermore, the moving speed of the sacrificing layer (120) is capable of being adjusted through driving the sacrificing layer (120) by the scroll driving devices (110) in accordance with the deposition conditions of the film coating process and the deposition speed of various reactive substances. [0065] In addition, in the disclosure, the fact that there is no clearance between the sacrificing layer (120) and the exterior surface of the electrode structures makes gas-flow of the reacting gas capable of flow to the plasma generated area along the sacrificing layer (120). In other words, not only the sacrificing layer (120) is capable of preventing the reacting gas from directly contacting with the first electrode structure (20) but also the sacrificing layer (120) is capable of isolating the reacting gas to flow into the other area causing deposition.

What is more, in the disclosure, the gas-flow passing through the precursor gas-import device (130) furnished in the plasma generated area is capable of reaching the objective of rectifying, distributively throttling, and further throttling to provide uniform gas-flow to the plasma generated area. Besides, since the stop part (138) of the precursor gas-import device (130) possesses the function of shielding and limiting the flowing direction of the gas, it is capable of assuring the flowing of the gas, which is uniformly rectified through the precursor gas-import device (130), into the plasma generated area.

Furthermore, the fact that the precursor gas-import device (130) is capable of horizontally adjusting the distance to the plasma generated area not only can adjust the gas importing distance in accordance with the deposition conditions of the film coating process and the deposition speed of various reactive substances, the blocking of the deposition substance that affects the flow of the gas-flow of the reacting gas can also be avoided.

It will become apparent to those people skilled in the art that various modifications and variations can be made to the structure of the disclosure without departing from the scope or spirit of the disclosure. In view of the foregoing description, it is intended that all the modifications and variation fall within the scope of the following appended claims and their equivalents.

What is claimed is:

1. An electrode contamination-proof device, comprising:
a first electrode structure;
a second electrode structure oppositely disposing and having a space with respect to the first electrode structure;
a sacrificing layer being positioned between the first electrode structure and the second electrode structure, is capable of moving and tightly clinging on the exterior surface for isolating from the first electrode structure; and
a scroll driving device driving the sacrificing layer to scroll in the scroll driving devices.

2. The electrode contamination-proof device as claimed in claim 1, wherein there is no clearance between the first electrode structure and the sacrificing layer.

3. The electrode contamination-proof device as claimed in claim 1, wherein the sacrificing layer is a dielectric film with dielectric constant being between 2 and 10.

4. The electrode contamination-proof device as claimed in claim 1, wherein the material of the sacrificing layer comprises Polyimide (PI), Polyethylene terephthalate (PET), Polymethylmethacrylate (PMMA, Acryl plastic) or glass.

5. The electrode contamination-proof device as claimed in claim 1, wherein the scroll driving devices comprises a first rolling element and a second rolling element; the sacrificing layer having an oppositely disposed first end fitting on the roller of the first rolling element and a second end fitting on the roller of the second rolling element; As the scroll driving devices drives the sacrificing layer, the sacrificing layer moves from first rolling element to second rolling element and tightly clings to the exterior surface of the first electrode structure while the second electrode structure receives the necessarily-to-be-changed sacrificing layer transported from the first rolling element.

6. The electrode contamination-proof device as claimed in claim 1, wherein the first electrode structure and the second electrode structure are cylindrical electrodes. elliptical electrodes, rectangular electrodes, or flat-plate type electrodes.

7. A film coating system, comprising:
a first electrode structure;
a second electrode structure oppositely disposing and having a space with respect to the first electrode structure;
a substrate furnished in the second electrode structure is positioned between the first electrode structure and the second electrode structure;
a sacrificing layer being positioned between the first electrode structure and the second electrode structure, is capable of moving and tightly clinging on the exterior surface for isolating from the first electrode structure; and
a scroll driving device driving the sacrificing layer to scroll in the scroll driving devices.

8. The film coating system as claimed in claim 7, further comprising:
a precursor gas-import device adjacent to the first electrode structure and the sacrificing layer, and the portion that the sacrificing layer contacts the first electrode structure protrudes beyond the precursor gas-import device.

9. The film coating system as claimed in claim 8, further comprising:
a supporting frame connecting to the precursor gas-import device and having the first electrode structure, the sacrificing layer, and the scroll driving device furnished thereof.

10. The film coating system as claimed in claim 8, wherein the precursor gas-import device comprises a gas diffuser, a gas rectifier, and a gas spurt; the gas rectifier is positioned between the gas diffuser and the gas spurt, and the gas diffuser is communicative to both the gas diffuser and the gas spurt, besides, the gas spurt faces the first electrode structure.

11. The film coating system as claimed in claim 10, wherein the gas spurt comprises a stop part which is appeared in slant surface and a spur part, and the stop part is protruded beyond the spur part.

12. The film coating system as claimed in claim 10, wherein the gas diffuser includes a first ventilating part, a diffusing part, and a plurality of first throttling holes. The first ventilating part is a hollow body. The diffusing part is furnished at the first ventilating part while the plurality of first throttling holes is furnished at the diffusing part. The first ventilating part is communicative to the diffusing part and the plurality of first throttling holes. The gas rectifier includes a second ventilating part, a rectifying part, and a plurality of second throttling holes. The second ventilating part being a hollow body is communicative to the plurality of first throttling holes. The rectifying part is furnished at the second ventilating part while the plurality of second throttling holes is furnished at the rectifying part. The second ventilating part is communicative to the rectifying part and the plurality of second throttling holes. The gas spurt includes a third ventilating part and a plurality of third throttling holes. The third ventilating part being a hollow body is communicative to the plurality of second throttling holes and the third throttling holes.

13. The film coating system as claimed in claim 8, wherein the precursor gas-import device and the second electrode structure are apart by a distance.

14. The film coating system as claimed in claim 9, further comprising:
an elevating mechanism connecting to the supporting frame; the first electrode structure is connected to the elevating mechanism which is used for adjusting the space between the first electrode structure and the second electrode structure.

15. The film coating system as claimed in claim 14, wherein the elevating mechanism comprises a top seat and a connecting seat, the top seat is connected to the connecting seat, and the first electrode structure is furnished in the connecting seat.

16. The film coating system as claimed in claim 15, wherein the top seat comprises rotating member and a screw rod, the rotating member is connected to the screw rod, and the screw rod is combined with the connecting seat.

17. The film coating system as claimed in claim 14, further comprising a cooling water-pipe joint communicative to the first electrode structure.

18. The film coating system as claimed in claim 7, wherein the scroll driving devices comprises a first rolling element and a second rolling element, the sacrificing layer having a first end fitting on the roller of the first rolling element and a second end fitting on the roller of the second rolling element; as the scroll driving devices drives the sacrificing layer, the sacrificing layer moves from first rolling element to second rolling element and tightly clings to the exterior surface of the first electrode structure while the second electrode structure receives the sacrificing layer transported from the first rolling element.

19. The film coating system as claimed in claim 7, further comprising a driving device which is connected to the second electrode structure; and the driving device drives the second electrode structure to move.

20. A film coating system, comprising:
a first electrode structure;
a second electrode structure oppositely disposing and having a space with respect to the first electrode structure;
a substrate being positioned between the first electrode structure and the second electrode structure is used for isolating the second electrode structure;
a sacrificing layer being positioned between the first electrode structure and the second electrode structure, is capable of moving and tightly clinging on the exterior surface for isolating from the first electrode structure; and
a scroll driving device driving the sacrificing layer to scroll in the scroll driving devices.

21. The film coating system as claimed in claim 20, further comprising:
a precursor gas-import device adjacent to the first electrode structure and the sacrificing layer, and the portion that the sacrificing layer contacts the first electrode structure protrudes beyond the precursor gas-import device.

22. The film coating system as claimed in claim 21, further comprising:
a supporting frame connecting to the precursor gas-import device and having the first electrode structure, the sacrificing layer, and the scroll driving device furnished thereof.

23. The film coating system as claimed in claim 21, wherein the precursor gas-import device comprises a gas diffuser, a gas rectifier, and a gas spurt; the gas rectifier is positioned between the gas diffuser and the gas spurt, and the gas diffuser is communicative to both the gas diffuser and the gas spurt, besides, the gas spurt faces the first electrode structure.

24. The film coating system as claimed in claim 23, wherein the gas spurt comprises a stop part which is appeared in slant surface and a spur part, and the stop part is protruded beyond the spur part.

25. The film coating system as claimed in claim 23, wherein the gas diffuser includes a first ventilating part, a diffusing part, and a plurality of first throttling holes. The first ventilating part is a hollow body. The diffusing part is furnished at the first ventilating part while the plurality of first throttling holes is furnished at the diffusing part. The first ventilating part is communicative to the diffusing part and the plurality of first throttling holes. The gas rectifier includes a second ventilating part, a rectifying part, and a plurality of second throttling holes. The second ventilating part being a hollow body is communicative to the plurality of first throttling holes. The rectifying part is furnished at the second ventilating part while the plurality of second throttling holes is furnished at the rectifying part. The second ventilating part is communicative to the rectifying part and the plurality of second throttling holes. The gas spurt includes a spur part, a third ventilating part, and a plurality of third throttling holes. The third ventilating part being a hollow body is communicative to the plurality of second throttling holes and the third throttling holes.

26. The film coating system as claimed in claim 21, wherein the precursor gas-import device and the second electrode structure are apart by a distance.

27. The film coating system as claimed in claim 22, further comprising:
an elevating mechanism connecting to the supporting frame; the first electrode structure is connected to the elevating mechanism which is used for adjusting the space between the first electrode structure and the second electrode structure.

28. The film coating system as claimed in claim 27, wherein the elevating mechanism comprises a top seat and a connecting seat, the top seat is connected to the connecting seat, and the first electrode structure is furnished in the connecting seat.

29. The film coating system as claimed in claim 28, wherein the top seat comprises rotating member and a screw rod, the rotating member is connected to the screw rod, and the screw rod is combined with the connecting seat.

30. The film coating system as claimed in claim 27, further comprising a cooling water-pipe joint communicative to the first electrode structure.

31. The film coating system as claimed in claim 20, wherein the scroll driving devices comprises a first rolling element and a second rolling element, the sacrificing layer having a first end fitting on the roller of the first rolling element and a second end fitting on the roller of the second rolling element; as the scroll driving devices drives the sacrificing layer, the sacrificing layer moves from first rolling element to second rolling element and tightly clings to the exterior surface of the first electrode structure while the second electrode structure receives the sacrificing layer transported from the first rolling element.

32. The film coating system as claimed in claim 20, further comprising a driving device which is connected to the second electrode structure; and the driving device drives the second electrode structure to move.
